(19) United States
(12) Patent Application Publication
(10) Pub. No.: US 2023/0369081 A1
(43) Pub. Date: Nov. 16, 2023

(54) APPARATUS FOR PROCESSING SUBSTRATE AND SEMICONDUCTOR MANUFACTURING APPARATUS INCLUDING THE SAME

(71) Applicant: SEMES CO., LTD., Cheonan-si (KR)

(72) Inventors: Haewon Choi, Daejeon-si (KR); Anton Koriakin, Cheonan-si (KR); Joonho Won, Suwon-si (KR); Hyungseok Kang, Suwon-si (KR); Minwoo Kim, Seoul-si (KR)

(21) Appl. No.: 18/197,677

(22) Filed: May 15, 2023

(30) Foreign Application Priority Data
May 16, 2022 (KR) 10-2022-0059817

(51) Int. Cl. H01L 21/67; H01L 21/475

(52) U.S. Cl. CPC H01L 21/6715; H01L 21/6704; H01L 21/475; H01L 21/67167

(57) ABSTRACT

Provided is an apparatus for processing a substrate, the apparatus including: a processing chamber configured to provide a processing space; a fluid supply device configured to supply a supercritical fluid to the processing chamber; a fluid discharge device configured to discharge the supercritical fluid from the processing chamber; and a control device configured to control operations of the fluid supply device and the fluid discharge device, wherein the fluid supply device includes a first supply line connected to an upper portion of the processing chamber and a second supply line connected to a lower portion of the processing chamber, and the control device is configured to perform a plurality of first cycles in which the supercritical fluid is alternately supplied into the processing space through the first supply line and the second supply line to boost pressure in the processing space to a set pressure.

### CROSS-REFERENCE TO RELATED APPLICATION

This application is based on and claims priority under 35 U.S.C. § 119 to Korean Patent Application No. 10-2022-0059817, filed on May 16, 2022, in the Korean Intellectual Property Office, the disclosure of which is incorporated by reference herein in its entirety.

### BACKGROUND

### 1. Field

The disclosure relates to an apparatus for processing a substrate and a semiconductor manufacturing apparatus including the apparatus for processing the substrate. More particularly, the disclosure relates to an apparatus for processing a substrate in which contamination due to a residue may be prevented and collapse of patterns may be enhanced, and a semiconductor manufacturing apparatus including the apparatus for processing the substrate.

### 2. Description of the Related Art

As the miniaturization of semiconductor devices is required, an extreme ultra-violet (EUV) lithography method having a very short wavelength (about 13.5 nm) has been suggested. By using EUV lithography, photoresist patterns having a small horizontal dimension and a high aspect ratio can be formed. Meanwhile, in order to prevent the photoresist patterns from collapsing in a process of forming fine photoresist patterns, a process using a supercritical fluid has been proposed, but a substrate may be contaminated by a residue during a manufacturing process of a semiconductor device.

### SUMMARY

Provided is an apparatus for processing a substrate in which contamination due to a residue may be prevented and collapse of patterns may be prevented, and a semiconductor manufacturing apparatus including the apparatus for processing the substrate.

Additional aspects will be set forth in part in the description which follows and, in part, will be apparent from the description, or may be learned by practice of the presented embodiments of the disclosure.

According to an aspect of the disclosure, an apparatus for processing a substrate includes a processing chamber configured to provide a processing space in which a substrate is to be processed, a fluid supply device configured to supply a supercritical fluid to the processing chamber, a fluid discharge device configured to discharge the supercritical fluid from the processing chamber, and a control device configured to control operations of the fluid supply device and the fluid discharge device, wherein the fluid supply device includes a first supply line connected to an upper portion of the processing chamber and a second supply line connected to a lower portion of the processing chamber, and the control device is configured to perform a plurality of first cycles in which the supercritical fluid is alternately supplied into the processing space through the first supply line and the second supply line to boost pressure in the processing space to a set pressure.

The set pressure may be 80 bar to 150 bar.

The control device may be configured to alternately supply the supercritical fluid through the first supply line for a first time and through the second supply line for a second time, and the first time and the second time may be independently selected from the range of 1 second to 10 seconds.

The first time and the second time may be the same.

The control device may be further configured to supply the supercritical fluid through the second supply line preceding the first supply line.

The first cycles may be performed 8 to 16 times.

The control device may be further configured to perform second cycles in which the pressure in the processing space is alternately decreased and increased, after the first cycles are performed.

The second cycles are performed 1 to 32 times.

A pressure difference in the processing space generated as the second cycles are performed, may be selected from the range of 5 bar to 75 bar.

The second cycles may be performed in such a way that the supercritical fluid is alternately supplied through the first supply line and is discharged through the fluid discharge device.

The control device may be further configured to discharge the supercritical fluid from the processing chamber through the fluid discharge device, after the second cycles are performed.

According to another aspect of the disclosure, a semiconductor manufacturing apparatus includes a first chamber module configured to coat a photoresist on a substrate, a second chamber module configured to bake the photoresist on the substrate, a third chamber module configured to irradiate an extreme ultraviolet (EUV) through an exposure mask onto the photoresist on the substrate, a fourth chamber module configured to provide a developing solution to the exposed photoresist, a fifth chamber module configured to supply a supercritical fluid to the substrate coated with the photoresist to which the developing solution is provided, and a substrate transfer device configured to transfer the substrate between the first through fifth modules, wherein the fifth chamber module includes a processing chamber configured to provide a processing space in which a substrate is to be processed, a fluid supply device configured to supply a supercritical fluid to the processing chamber, a fluid discharge device configured to discharge the supercritical fluid from the processing chamber, and a control device configured to control operations of the fluid supply device and the fluid discharge device, and the fluid supply device includes a first supply line connected to an upper portion of the processing chamber and a second supply line connected to a lower portion of the processing chamber, and the control device is configured to perform a plurality of first cycles in which the supercritical fluid is alternately supplied into the processing space through the first supply line and the second supply line to boost the pressure in the processing space to a set pressure.

The supercritical fluid may be carbon dioxide, and the developing solution may be a negative tone developing solution.

The control device may be configured to perform second cycles in which the pressure in the processing space is alternately decreased and increased, 1 to 32 times after the first cycles are performed.

A pressure difference in the processing space generated as the second cycles are performed, may be selected from the range of 5 bar to 75 bar.

The pressure in the processing space may be increased when the supercritical fluid is supplied through the first supply line, and the pressure in the processing space may be decreased when the supercritical fluid is discharged through the fluid discharge device.

According to another aspect of the disclosure, an apparatus for processing a substrate includes a processing chamber configured to provide a processing space in which a substrate is to be processed, wherein the substrate includes an extreme ultraviolet (EUV) photoresist layer exposed in the EUV and a developing solution for developing the EUV photoresist layer, a substrate support configured to support the substrate loaded into the processing space, a fluid supply device configured to supply a supercritical fluid to the processing chamber, a fluid discharge device configured to discharge the supercritical fluid from the processing chamber, and a control device configured to control operations of the fluid supply device and the fluid discharge device, and wherein the fluid supply device includes a first supply line connected to an upper portion of the processing chamber and a second supply line connected to a lower portion of the processing chamber, and the control device is configured to perform a plurality of first cycles in which the supercritical fluid is alternately supplied into the processing space through the first supply line and the second supply line to boost the pressure in the processing space to a set pressure.

The control device may be further configured to alternately supply the supercritical fluid through the first supply line for a first time and through the second supply line for a second time, and the first time and the second time may be independently selected from the range of 1 second to 10 seconds and may be the same.

The control device may be further configured to perform second cycles in which the pressure in the processing space is alternately decreased and increased, after the first cycles are performed, and the pressure in the processing space may be increased when the supercritical fluid is supplied through the first supply line, and the pressure in the processing space may be decreased when the supercritical fluid is discharge through the fluid discharge device.

The second cycles may be performed 1 to 32 times.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a semiconductor manufacturing apparatus according to an embodiment;

FIG. 2 is a cross-sectional view schematically illustrating a fifth chamber module according to an embodiment;

FIG. 3 is a schematic chart illustrating a method of supplying and discharging a supercritical fluid to clean, remove, and dry a developing solution on the substrate according to an embodiment; and

FIGS. 4A through 4C are views illustrating the shape of the developing solution on the substrate according to the supply of the supercritical fluid.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Embodiments of the technical spirit of the disclosure will be described in detail with reference to the accompanying drawings. The same reference numerals are used for the same components on the drawings, and a redundant description thereof is omitted.

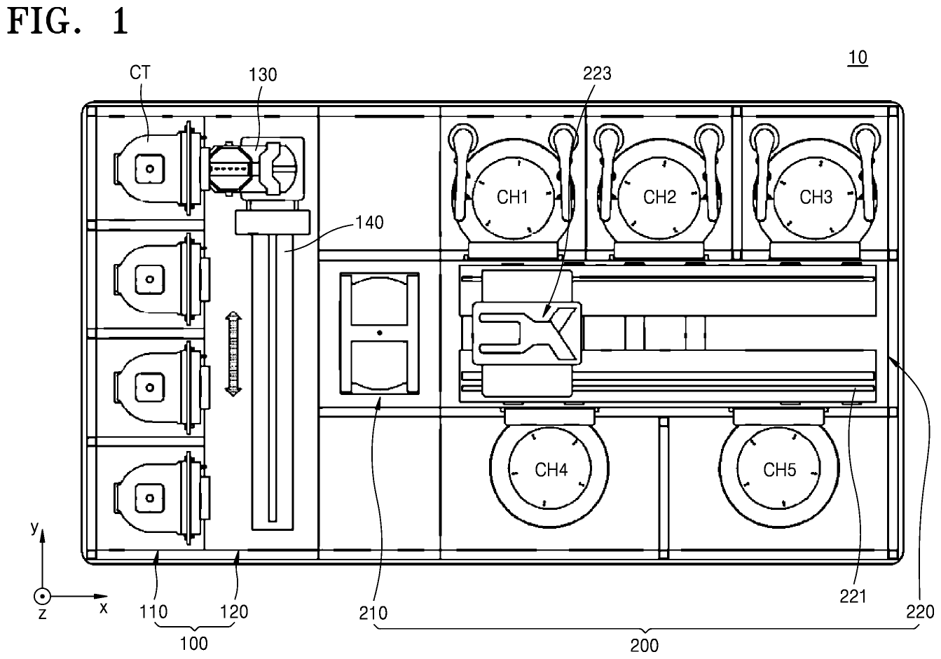

FIG. 1 is a cross-sectional view illustrating a semiconductor manufacturing apparatus 10 according to an embodiment.

Referring to FIG. 1, the semiconductor manufacturing apparatus 10 may include an index module 100 and a processing module 200.

The index module 100 may include a load port 110 and a transfer frame 120. The load port 110, the transfer frame 120, and the processing module 200 may be sequentially arranged in a row. Hereinafter, a direction in which the load port 110, the transfer frame 120 and the processing module 200 are arranged in a row, is defined as an X direction, and a horizontal direction perpendicular to the X direction is defined as a Y direction, and a direction perpendicular to the X direction and the Y direction, respectively, is defined as a Z direction.

A container CT in which a substrate W is accommodated, is seated on the load port 110. A plurality of load ports 110 are provided, and may be arranged in a row in the Y direction. Four load ports 110 are shown in the drawings, and the number of load ports 110 may be increased or decreased according to conditions such as the process efficiency and/or installation area of the processing module 200. The container CT may include a plurality of slots configured to support edges of the substrate W. The plurality of slots may be spaced apart from each other in the Z direction. Thus, the plurality of substrates W may be mounted in the container CT in the Z direction. The container CT may be, for example, a front opening unified pod (FOUP).

The transfer frame 120 may be configured to transfer the substrate W between the container CT on the load port 110 and a buffer chamber 210 of the processing module 200. The transfer frame 120 may include an index robot 130 and an index rail 140. The index rail 140 may extend in the Y direction. The index robot 130 may be installed on the index rail 140 and may move linearly in the Y direction along the index rail 140.

The processing module 200 may include the buffer chamber 210, a transfer chamber 220, first through fifth chamber modules CH1, CH2, CH3, CH4, and CH5. The transfer chamber 220 may extend in the X direction. In some embodiments, the first through fifth chamber modules CH1, CH2, CH3, CH4, and CH5 may be spaced apart from each other with the transfer chamber 220 therebetween in the Y direction. Also, the first through fifth chamber modules CH1, CH2, CH3, CH4, and CH5 may be arranged in the X direction. In other embodiments, some of the first through fifth chamber modules CH1, CH2, CH3, CH4, and CH5 may be stacked in the Z direction.

In the drawings, the arrangement of the first through fifth chamber modules CH1, CH2, CH3, CH4, and CH5 is illustrative, and if necessary, the first through fifth chamber modules CH1, CH2, CH3, CH4, and CH5 may be arranged in various ways. For example, all of the first through fifth chamber modules CH1, CH2, CH3, CH4, and CH5 may be arranged only on one side surface of the transfer chamber 220.

The buffer chamber 210 may be disposed between the transfer frame 120 and the transfer chamber 220. The buffer chamber 210 may provide a space in which the substrate W is stored, between the transfer chamber 220 and the transfer frame 120. The buffer chamber 210 may include a plurality of slots that are an internal space in which the substrate W is stored. The plurality of slots may overlap each other and may be spaced apart from each other in the Z direction. The buffer chamber 210 may include an opening through which the substrate W may enter or exit and which is formed on a surface facing the transfer frame 120 and a surface facing the transfer chamber 220, respectively.

The transfer chamber 220 may transfer the substrate W between the buffer chamber 210 and the first through fifth chamber modules CH1, CH2, CH3, CH4, and CH5. A guide rail 221 and a substrate transfer device 223 may be positioned in the transfer chamber 220. The guide rail 222 may extend in the X direction. The substrate transfer device 223 may be installed on the guide rail 221 and may move linearly in the X direction along the guide rail 221. The substrate W may be transferred by the substrate transfer device 223 between the first through fifth chamber modules CH1, CH2, CH3, CH4, and CH5.

The first through fifth chamber modules CH1, CH2, CH3, CH4, and CH5 may perform a process on one substrate sequentially. For example, after a photoresist is coated onto the substrate carried in the first chamber module CH1, the photoresist on the substrate W may be baked in the second chamber module CH2.

The photoresist may be coated on the substrate W carried in the first chamber module CH1.

In example embodiments, the substrate W may include an IV-group semiconductor such as silicon (Si) or germanium (Ge), an IV-IV-group compound semiconductor such as silicon-germanium (SiGe) or silicon carbide (SiC), or an III-V-group compound semiconductor such as gallium arsenide (GaAs), indium arsenide (InAs), or indium phosphor (InP).

The photoresist coated on the substrate W may be exposed to an extreme ultraviolet (EUV), for example, and thus may be a photosensitive polymer material of which chemical properties are changed.

The photoresist may be coated by a method such as spin coating, spray coating, deep coating, or the like.

The photoresist on the substrate W may be baked in the second chamber module CH2. The baking may be performed, for example, at the temperature of about 80° C. to about 130° C. for about 40 seconds to about 100 seconds.

The EUV may be irradiated onto the photoresist on the substrate W through an exposure mask in the third chamber module CH3.

A developing solution may be provided to the exposed photoresist in the fourth chamber module CH4. The developing solution may be, for example, a non-polar organic solvent. The developing solution may be, for example, a developing solution capable of selectively removing a soluble region of the photoresist. In example embodiments, the developing solution may include aromatic hydrocarbon, cyclohexane, cyclohexanone, acyclic or cyclic ethers, acetates, propionate, butyrate, lactate, or a combination thereof. For example, n-butyl acetate (nBA), propylene glycol methyl ether (PGME), propylene glycol methyl ether acetate (PGME), γ-butyrolactone (GBL), isopropanol (IPA) or the like may be used for the developing solution.

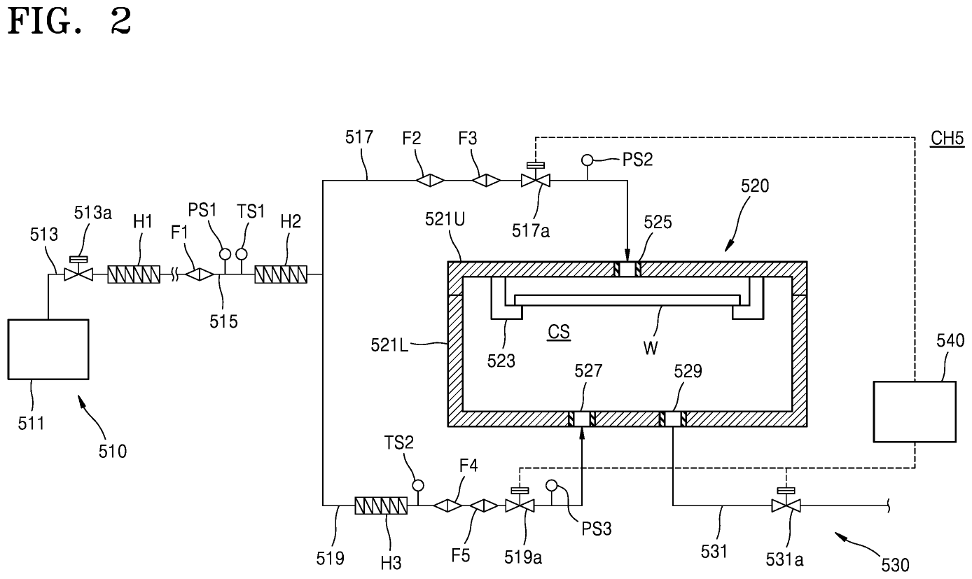

In the fifth chamber module CH5, the substrate W may be transferred from the fourth chamber module CH4, and the supercritical fluid may be alternately supplied to the substrate W through a first supply line (see 517 of FIG. 2) and a second supply line (see 519 of FIG. 2). Hereinafter, the fifth chamber module CH5 will be described in detail with reference to FIG. 2.

FIG. 2 is a cross-sectional view schematically illustrating the fifth chamber module CH5 according to an embodiment.

Referring to FIG. 2, the fifth chamber module CH5 may include a processing chamber 520 configured to provide a processing space CS for processing the substrate W, a fluid supply device 510 configured to supply the supercritical fluid to the processing chamber 520, a fluid discharge device 530 configured to discharge the supercritical fluid from the processing chamber 520, and a control device 540 configured to control the operation of the fluid supply device 510 and the fluid discharge device 530.

The processing chamber 520 may include an upper chamber body 521U, a lower chamber body 521L, and a substrate support 523.

The upper chamber body 521U and the lower chamber body 521L may provide the processing space CS in which the substrate W may be processed. For example, in the processing space CS, a drying process of drying the substrate W may be performed using the supercritical fluid.

The upper chamber body 521U and the lower chamber body 521L may be coupled to each other so as to be openable and closable to switch between a closed position where the processing space CS is sealed and an open position where the processing space CS is opened to the atmosphere. In example embodiments, the upper chamber body 521U may constitute an upper wall and portions of sidewalls of the processing chamber 520, and the lower chamber body 521L may constitute a lower wall and the other portions of sidewalls of the processing chamber 520. However, embodiments are not limited thereto, and for example, the upper chamber body 521U may constitute the upper wall of the processing chamber 520, and the lower chamber body 521L may constitute the lower wall of the processing chamber 520.

In example embodiments, switching between the closed position and the open position of the processing chamber 520 may be performed by a lifting member for performing raising or lowering of the upper chamber body 521U and/or the lower chamber body 521L, a driving member for driving the movement thereof, and a controller for controlling the movement thereof. For example, switching between the closed position and the open position of the processing chamber 520 may be performed by raising and lowering of the lower chamber body 521L.

In example embodiments, the substrate W may be carried in or carried out of the processing space CS according to switching between the closed position and the open position of the processing chamber 520. For example, when the processing chamber 520 is in the open position, the substrate W may be carried in the processing space CS or carried out of the processing space CS.

A first support port 525 may be disposed in the upper chamber body 521U. The first support port 525 may be connected to the first supply line 517, and the supercritical fluid may be supplied in a direction toward an upper surface of the substrate W through the first supply port 525.

A second supply port 527 and a discharge port 529 may be disposed in the lower chamber body 521L. The second support port 527 may be connected to the second supply line 519, and the supercritical fluid may be supplied in a direction toward a lower surface of the substrate W through the second supply port 527. The discharge port 529 may be connected to the discharge line 531, and after a drying process of the substrate W is performed, the supercritical fluid may be discharged from the processing space CS through the discharge port 529.

The substrate support 523 may be disposed in the processing space CS. For example, the substrate support 523 may be coupled to the upper chamber body 521U and may be disposed in a direction toward the substrate W. A plurality of substrate supports 523 may be provided. For example, two substrate supports 523 may be present and may be disposed to be linearly symmetrical to each other based on a virtual line located in the center of the processing chamber 520. The substrate support 523 may support the substrate W provided in the processing space CS. For example, the substrate support 523 may support a lower surface of an edge region of the substrate W.

The fluid supply device 510 may include a fluid storage tank 511, a first upstream supply line 513, a first upstream supply valve 513a, a second upstream supply line 515, a first supply line 517, a first supply valve 517a, a second supply line 519, and a second supply valve 519a.

The fluid storage tank 511 may keep the supercritical fluid in a supercritical state. The supercritical fluid may be, for example, carbon dioxide in the supercritical state. For example, the temperature of carbon dioxide in the supercritical state may be about 60° C., and the pressure of carbon dioxide in the supercritical state may be about 80 bar.

The first upstream supply line 513 may be connected to the fluid storage tank 511. The supercritical fluid supplied from the fluid storage tank 511 may be supplied to the second upstream supply line 515 through the first upstream supply line 513.

The first upstream supply valve 513a may be disposed in the first upstream supply line 513. According to the operation of the first upstream supply valve 513a, the supply of the supercritical fluid through the first upstream supply line 513 may be adjusted.

The second upstream supply line 515 may be connected to the first upstream supply line 513. The supercritical fluid supplied through the first upstream supply line 513 may be supplied to the first supply line 517 or the second supply line 519 via the second upstream supply line 515.

Although not shown in FIG. 2, the fluid supply device 510 may include a plurality of sub supply lines (not shown) located between the first upstream supply line 513 and the second upstream supply line 515. The plurality of sub supply lines may be diverged from the first upstream supply line 513 and may merge back into the second upstream supply line 515. In this case, a plurality of sub supply valves (not shown) may be respectively connected to the plurality of sub supply lines. In an example embodiment, the plurality of sub supply valves may be metering valves.

The first supply line 517 may be diverged from the second upstream supply line 515 and may be connected to an upper surface of the upper chamber body 521U. The supercritical fluid may be supplied in a direction toward the upper surface of the substrate W provided in the processing space CS from the first supply port 525 via the first supply line 517.

The first supply line valve 517a may be disposed in the first supply line 517. The first supply line valve 517a may control the supply of the supercritical fluid through the first supply line 517. For example, when the first supply line valve 517a is opened, the supercritical fluid may be supplied into the processing space CS through the first supply line 517. The operation of the first supply line valve 517a may be controlled by the control device 540.

The second supply line 519 may be diverged from the second upstream supply line 515 and may be connected to a lower surface of the lower chamber body 521L. The supercritical fluid may be supplied in a direction toward the lower surface of the substrate W provided in the processing space CS from the second supply port 527 via the second supply line 519.

The second supply line valve 519a may be connected to the second supply line 519. The second supply line valve 519a may control the supply of the supercritical fluid through the second supply line 519. For example, when the second supply line valve 519a is opened, the supercritical fluid may be supplied into the processing space CS through the second supply line 519. The operation of the second supply line valve 519a may be controlled by the control device 540.

The fluid supply device 510 may include a plurality of heaters H1, H2, and H3. For example, the fluid supply device 510 may include three heaters H1, H2, and H3, and the first heater H1 may be disposed in the first upstream supply line 513, and the second heater H2 may be disposed in the second upstream supply line 515, and the third heater H3 may be disposed in the second supply line 519. However, embodiments are not limited thereto, and if necessary, the number of heaters may increase or decrease. The plurality of heaters H1, H2, and H3 may adjust the temperature of the supercritical fluid flowing through each of the supply lines 513, 515, 517, and 519.

The fluid supply device 510 may further include a plurality of filters F1, F2, F3, F4, and F5. For example, the fluid supply device 510 may include five filters F1, F2, F3, F4, and F5, and the first filter F1 may be disposed in the second upstream supply line 515, and the second filter F2 and the third filter F3 may be disposed in the first supply line 517, and the fourth filter F4 and the fifth filter F5 may be disposed in the second supply line 519. However, embodiments are not limited thereto, and if necessary, the number of filters may increase or decrease. The plurality of filters F1, F2, F3, F4, and F5 may be different types of filters. For example, the first filter F1, the second filter F2, and the fourth filter F4 may be micro filters (MFs), and the third filter F3 and the fifth filter F5 may be ultra filters (UFs). However, embodiments are not limited thereto, and all of the plurality of filters F1, F2, F3, F4, and F5 may be the same type of filters or different types of filters. The plurality of filters F1, F2, F3, F4, and F5 may filter the supercritical fluid flowing through each of the supply lines 515, 517, and 519.

The fluid supply device 510 may further include a plurality of pressure sensors PS1, PS2, and PS3. For example, the fluid supply device 510 may include three pressure sensors PS1, PS2, and PS3, and the first pressure sensor PS1 may be disposed in the second upstream supply line 515, and the second pressure sensor PS2 may be disposed in the first supply line 517, and the third pressure sensor PS3 may be disposed in the second supply line 519. However, embodiments are not limited thereto, and if necessary, the number of pressure sensors may increase or decrease. The plurality of pressure sensors PS1, PS2, and PS3 may measure the pressure of the supercritical fluid flowing through the supply lines 515, 517, and 519.

The fluid supply device 510 may further include a plurality of temperature sensors TS1 and TS2. For example, the fluid supply device 510 may include two temperature sensors TS1 and TS2, and the first temperature sensor TS1 may be disposed in the second upstream supply line 515, and the second temperature sensor TS2 may be disposed in the second supply line 519. However, embodiments are not limited thereto, and if necessary, the number of temperature sensors may increase or decrease. The plurality of temperature sensors TS1 and TS2 may measure the pressure of the supercritical fluid flowing through the supply lines 515 and 519.

The fluid discharge device 530 may include a discharge line 531 and a discharge valve 531a.

The discharge line 531 may be connected to a lower surface of the lower chamber body 521L. After the process of drying the substrate W using the supercritical fluid in the processing chamber 520 is performed, the supercritical fluid may be discharged from the processing space CS through the discharge line 531 via the discharge port 529.

The discharge valve 531a may be connected to the discharge line 531. The discharge valve 531a may control the discharge of the supercritical fluid through the discharge line 531. For example, when the discharge valve 531a is opened, the supercritical fluid may be discharged from the processing space CS through the discharge line 531.

The control device 540 may control the operation of the first supply valve 517a, the second supply valve 519a, and the discharge valve 531a. For example, the control device 540 may be configured to transmit/receive an electrical signal to/from the first supply valve 517a, the second supply valve 519a, and the discharge valve 531a, thereby controlling the operation of the first supply valve 517a, the second supply valve 519a, and the discharge valve 531a.

The control device 540 may be implemented with hardware, firmware, software or any combination thereof. For example, the control device 540 may be a computing device, such as a workstation computer, a desktop computer, a laptop computer, a tablet computer, or the like. For example, the control device 540 may include a memory device such as read only memory (ROM), random access memory (RAM), or the like and a processor configured to execute a certain arithmetic operation and algorithm, for example, a microprocessor, a central processing unit (CPU), graphics processing unit (GPU), or the like. Also, the control device 540 may include a receiver for receiving the electrical signal and a transmitter for transmitting the electrical signal.

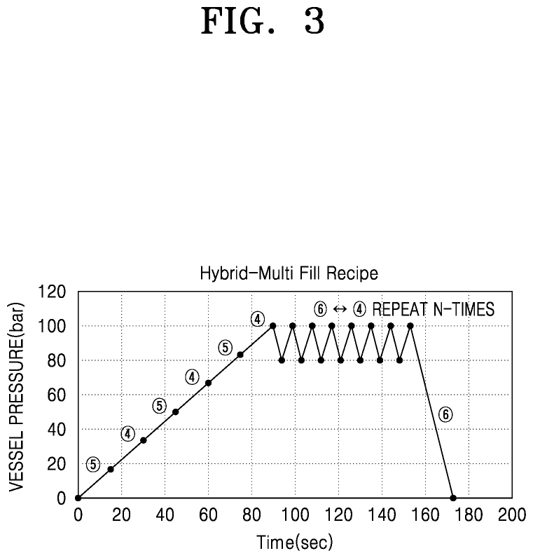

Hereinafter, the operation of an apparatus for processing a substrate using the control device 540 according to an embodiment will be described in detail with reference to FIGS. 2 and 3.

FIG. 3 is a schematic chart illustrating a method of supplying and discharging a supercritical fluid to clean, remove, and dry a developing solution on the substrate according to an embodiment. In FIG. 3, the X-axis represents time, and the Y-axis represents pressure in the processing space CS.

Referring to FIG. 3, the control device 540 may be configured to perform a plurality of first cycles in which the supercritical fluid is alternately supplied into the processing space CS through the first supply line 517 and the second supply line 519 to boost the pressure in the processing space CS to a set pressure. The plurality of first cycles may be performed, for example, in such a way that the first supply valve 517a and the second supply valve 519a are alternately opened/closed by the control device 540.

In an example embodiment, the set pressure may be 80 bar to 150 bar, however, embodiments are not limited thereto.

In an example embodiment, the control device 540 may be configured to alternately supply the supercritical fluid through the first supply line 517 for a first time and through the second supply line 519 for a second time. For example, the control device 540 may supply alternately the supercritical fluid into the processing space CS by opening the first supply valve 517a and closing the second supply valve 519a for the first time and then the supercritical fluid into the processing space CS by closing the first supply valve 517a and opening the second supply valve 519a for the second time.

In an example embodiment, each of the first time and the second time may be independently selected from the range of 1 second to 10 seconds. In an example embodiment, the first time and the second time may be the same. For example, the control device 540 may open alternately the first supply valve 517a for 10 seconds and may close the second supply valve 519a and then may close the first supply valve 517a and may open the second supply valve 519a for the next 10 seconds.

In an example embodiment, the control device 540 may be configured to supply the supercritical fluid through the second supply line 519 for a second time firstly and then to supply the supercritical fluid through the first supply line 517 for the first time. For example, the control device 540 may supply the supercritical fluid into the processing space CS by closing the first supply valve 517a and opening the second supply valve 519a for 10 seconds and then may supply the supercritical fluid into the processing space CS by closing the second supply valve 519a and opening the first supply valve 517a for the next 10 seconds.

In an example embodiment, the first cycles may be performed 8 to 16 times. However, embodiments are not limited thereto, and the first cycle may also be performed at a smaller or larger number of times than 8 to 16 times in response to a value of the first time and a value of the second time.

In an example embodiment, the control device 540 may perform second cycles in which the pressure in the processing space CS is alternately decreased and increased, after the first cycles are performed. The second cycles may be performed, for example, in such a way that the first supply valve 517a and the discharge valve 531a are alternately opened/closed by the control device 540.

In an example embodiment, the second cycles may be performed 1 to 32 times.

In an example embodiment, the pressure difference by performing the second cycles may be selected from the range of 5 bar to 75 bar. For example, the pressure difference may be 20 bar.

In an example embodiment, the second cycles may be performed in such a way that the supercritical fluid is alternately supplied into the processing space CS through the first supply line 517 and the supercritical fluid is discharged through the fluid discharge line 531. That is, in the second cycles, the pressure in the processing space CS may be increased when the supercritical fluid is supplied into the processing space CS through the first supply line 517, and the pressure in the processing space CS may be decreased when the supercritical fluid is discharged into the processing space CS through the discharge line 531.

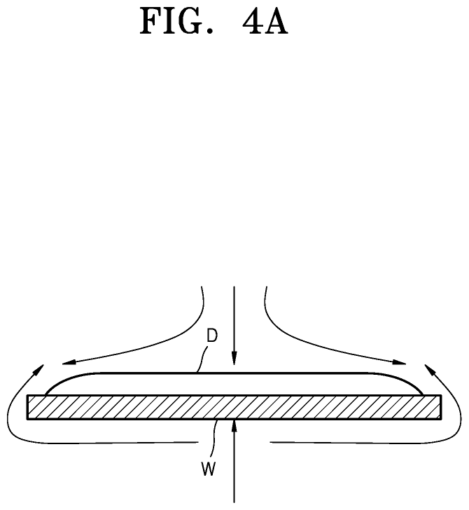

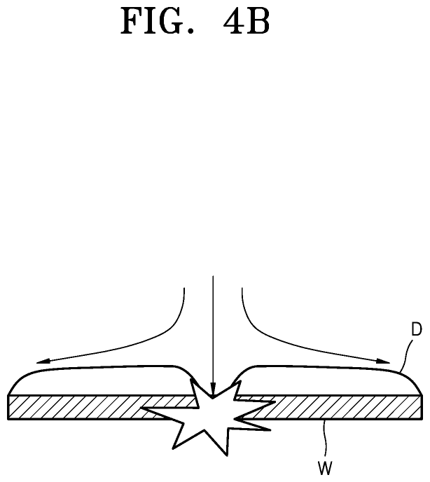

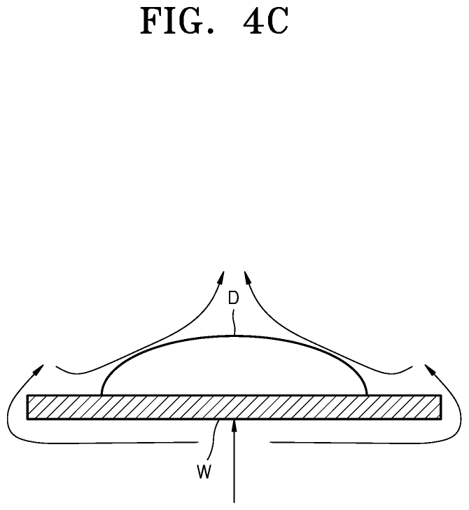

According to an example embodiment, when performing the process of drying the substrate W, the supercritical fluid may be alternately supplied in a direction toward the upper surface of the substrate W and a direction toward the lower surface of the substrate W so that a developing solution (see D of FIG. 4A) on the substrate W may be uniformly dried, patterns formed on the substrate W may be prevented from collapsing during the drying process and reverse contamination of the substrate W due to the photoresist material remaining on the lower surface of the substrate W may be prevented.

FIGS. 4A through 4C are views illustrating the shape of the developing agent on the substrate according to supply of the supercritical fluid. FIG. 4A illustrates the case where the supercritical fluid is alternately supplied through the first supply line 517 and the second supply line 519 according to an embodiment, and FIG. 4B illustrates the case where the supercritical fluid is supplied only in a direction toward the upper surface of the substrate, and FIG. 4C illustrates the case where the supercritical fluid is supplied only in a direction toward the lower surface of the substrate.

Referring to FIG. 4A, when the supercritical fluid is alternately supplied according to an embodiment, the developing solution D on the substrate W may be comparatively uniformly dried.

On the other hand, referring to FIG. 4B, when the supercritical fluid is supplied only in a direction toward the upper surface of the substrate W, the developing solution D coated in the central region of the substrate W may be relatively rapidly dried, whereas the developing solution D coated in the edge region of the substrate W may be relatively slowly dried. Thus, the efficiency of the drying process may be lowered, and patterns formed in the central region of the substrate W may collapse.

In addition, referring to FIG. 4C, when the supercritical fluid is supplied only in a direction toward the lower surface of the substrate W, the developing solution D coated in the edge region of the substrate W may be relatively rapidly dried, whereas the developing solution D coated in the central region of the substrate W may be relatively slowly dried. Thus, the efficiency of the drying process may be lowered, and reverse contamination of the substrate W due to a photoresist residue remaining on the lower surface of the substrate W may be prevented.

That is, referring to FIGS. 4A through 4C, it may be ascertained that, when the supercritical fluid is alternately supplied in directions toward the upper surface and the lower surface of the substrate W according to an embodiment, the developing solution D on the substrate W may be uniformly dried, and patterns formed on the substrate W may be prevented from collapsing during the drying process, and reverse contamination of the substrate W due to a photoresist material that remains in the lower surface of the substrate W may be prevented.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An apparatus for processing a substrate, the apparatus comprising:
a processing chamber configured to provide a processing space in which a substrate is to be processed;
a fluid supply device configured to supply a supercritical fluid to the processing chamber;
a fluid discharge device configured to discharge the supercritical fluid from the processing chamber; and
a control device configured to control operations of the fluid supply device and the fluid discharge device,
wherein the fluid supply device comprises a first supply line connected to an upper portion of the processing chamber and a second supply line connected to a lower portion of the processing chamber, and the control device is configured to perform a plurality of first cycles in which the supercritical fluid is alternately supplied into the processing space through the first supply line and the second supply line to boost pressure in the processing space to a set pressure.

2. The apparatus of claim 1, wherein the set pressure is 80 bar to 150 bar.

3. The apparatus of claim 1, wherein the control device is further configured to alternately supply the supercritical fluid through the first supply line for a first time and the supercritical fluid through the second supply line for a second time, and the first time and the second time are independently selected from a range of 1 second to 10 seconds.

4. The apparatus of claim 3, wherein the first time and the second time are same.

5. The apparatus of claim 1, wherein the control device is further configured to supply the supercritical fluid through the second supply line preceding the first supply line.

6. The apparatus of claim 1, wherein the plurality of first cycles are performed 8 to 16 times.

7. The apparatus of claim 1, wherein the control device is further configured to perform second cycles in which pressure in the processing space is alternately decreased and increased, after the first cycles are performed.

8. The apparatus of claim 7, wherein the second cycles are performed 1 to 32 times.

9. The apparatus of claim 7, wherein a pressure difference in the processing space generated by performing the second cycles is selected from a range of 5 bar to 75 bar.

10. The apparatus of claim 7, wherein the second cycles are performed in such a way that the supercritical fluid is alternately supplied through the first supply line and the supercritical fluid is discharged through the fluid discharge device.

11. The apparatus of claim 7, wherein the control device is further configured to discharge the supercritical fluid from the processing chamber through the fluid discharge device, after the second cycles are performed.

12. A semiconductor manufacturing apparatus comprising:
a first chamber module configured to coat a photoresist onto a substrate;
a second chamber module configured to bake the photoresist on the substrate;
a third chamber module configured to irradiate an extreme ultraviolet (EUV) onto the photoresist on the substrate through an exposure mask;
a fourth chamber module configured to provide a developing solution to the exposed photoresist;
a fifth chamber module configured to supply a supercritical fluid to the substrate coated with the photoresist to which the developing solution is provided; and
a substrate transfer device configured to transfer the substrate between the first through fifth chamber modules,
wherein the fifth chamber module comprises:
a processing chamber configured to provide a processing space in which a substrate is to be processed;
a fluid supply device configured to supply a supercritical fluid to the processing chamber; a fluid discharge device configured to discharge the supercritical fluid from the processing chamber; and
a control device configured to control operations of the fluid supply device and the fluid discharge device, and
the fluid supply device comprises a first supply line connected to an upper portion of the processing chamber and a second supply line connected to a lower portion of the processing chamber, and the control device is configured to perform a plurality of first cycles in which the supercritical fluid is alternately supplied into the processing space through the first supply line and the second supply line to boost pressure in the processing space to a set pressure.

13. The semiconductor manufacturing apparatus of claim 12, wherein the supercritical fluid comprises carbon dioxide.

14. The semiconductor manufacturing apparatus of claim 12, wherein the control device is further configured to perform second cycles in which pressure in the processing space is alternately decreased and increased, 1 to 32 times after the first cycles are performed.

15. The semiconductor manufacturing apparatus of claim 14, wherein a pressure difference in the processing space generated by performing the second cycles is selected from a range of 5 bar to 75 bar.

16. The semiconductor manufacturing apparatus of claim 13, wherein the pressure in the processing space is increased when the supercritical fluid is supplied through the first supply line and the pressure in the processing space is decreased when the supercritical fluid is discharged through the fluid discharge device.

17. An apparatus for processing a substrate, the apparatus comprising:
a processing chamber configured to provide a processing space in which a substrate is to be processed, wherein the substrate comprises an extreme ultraviolet (EUV) photoresist layer exposed to the EUV and a developing solution for developing the EUV photoresist layer;
a substrate support configured to support the substrate loaded into the processing chamber;
a fluid supply device configured to supply a supercritical fluid to the processing chamber;
a fluid discharge device configured to discharge the supercritical fluid from the processing chamber; and
a control device configured to control operations of the fluid supply device and the fluid discharge device,
wherein the fluid supply device comprises a first supply line connected to an upper portion of the processing chamber and a second supply line connected to a lower portion of the processing chamber, and
the control device is configured to perform a plurality of first cycles in which the supercritical fluid is alternately supplied into the processing space through the first supply line and the second supply line to boost pressure in the processing space to a set pressure.

18. The apparatus of claim 17, wherein the control device is further configured to alternately supply the supercritical fluid through the first supply line for a first time and the supercritical fluid through the second supply line for a second time, and the first time and the second time are independently selected from a range of 1 second to 10 seconds and same.

19. The apparatus of claim 17, wherein the control device is further configured to perform second cycles in which pressure in the processing space is alternately decreased and increased, after the first cycle is performed, and the pressure in the processing space is increased when the supercritical fluid is supplied through the first supply line, and the pressure in the processing space is decreased when the supercritical fluid is discharged through the fluid discharge device.

20. The apparatus of claim 19, wherein the second cycles are performed 1 to 32 times.
